(19) United States
(12) Patent Application Publication
(10) Pub. No.: US 2001/0022384 A1
(43) Pub. Date: Sep. 20, 2001

(54) Resistive structure integrated in a semiconductor substrate

(76) Inventors: Salvatore Leonardi, Aci S. Antonio (IT); Roberto Modica, Catania (IT)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 09/747,425

(22) Filed: Dec. 21, 2000

(30) Foreign Application Priority Data
Dec. 21, 1999 (IT) MI99A002667

(51) Int. Cl. H01L 29/00

(52) U.S. Cl. 257/536

(57) ABSTRACT

A resistive structure integrated in a semiconductor substrate and having a suitably doped polysilicon region that is completely surrounded by a dielectric region so that the resistive structure is isolated electrically from other components jointly integrated in the semiconductor substrate.

### TECHNICAL FIELD

This invention relates to a resistive structure integrated in a semiconductor substrate, and more specifically to a resistive structure integrated in a semiconductor substrate and having a suitably doped polysilicon region.

The invention relates, particularly but not exclusively, to a high-voltage resistive structure for integration in a semiconductor substrate along with power devices, and this description covers this field of application for convenience of illustration only.

### BACKGROUND OF THE INVENTION

As is well known, high-voltage resistive structures integrated in a semiconductor substrate are used extensively in IC power devices, e.g. VIPower devices.

VIPower devices have a region where power devices are formed (power region) and a region where signal devices are formed (signal region) jointly integrated in the same chip. Some applications require that provisions be made in the signal region for dividing a substrate voltage. This requirement can be met by having a resistive structure connected between the substrate and the control region of the signal device. Consequently, the resistive structure is to accept a substrate voltage Vs that is recognized to attain values as high as 2 kV in VIPower devices (and accordingly, referred to as a high-voltage resistive structure or HV resistor).

Shown in FIGS. 1 and 2 are electric diagrams of two possible applications of high-voltage resistive structures.

In particular, FIG. 1 shows a first circuit structure, generally designated C1, which comprises a series of an NPN bipolar component Q1 and a resistor R1 connected between a first or substrate voltage reference Vs and a second or ground voltage reference GND, the resistor R1 having a first terminal connected to the emitter region of the bipolar component Q1.

The first circuit structure C1 further comprises a Zener diode D1, which is reverse bias-connected between the base terminal of the bipolar component Q1 and a second terminal of the resistor R1. Also, a high-voltage resistor R_{HV} is connected between the collector region and the base region of the bipolar component Q1.

As a current I1 flows through the resistor R_{HV}, the bipolar component Q1 is turned on to drive low voltage circuitry BT connected to the emitter region of the bipolar component Q1. The strength of the current I1 flowing through the resistor R_{HV} is obviously dependent on the substrate voltage Vs, as well as on the resistance value of the resistor RHV.

To illustrate another exemplary application of high-voltage resistors, a second circuit structure, generally designated C2, is shown in FIG. 2 which comprises two circuit legs 1a and 2a having a node A in common and being connected between a substrate voltage reference Vs and ground GND.

In particular, the first leg 1a comprises a chain of Zener diodes D2, D3, and D4 connected to the base region of a first bipolar component Q2 which is biased by a resistor R2 placed between its base and emitter terminals.

The second leg 2a comprises another transistor R3 which is series-connected to the emitter region of a second bipolar component Q3, the latter being controlled by a source of constant voltage Vb, e.g., a battery. A high-voltage resistor R_{HV} is connected between the substrate voltage reference Vs and the node A.

With this design of the second circuit structure C2, the voltage at the node A can be used as a reference value to allow conduction to occur through either the leg 1 or the leg 2 according to the voltage value Vz presented across the chain of Zener diodes D2, D3, D4, the battery voltage Vb, and the voltages of other circuitry components.

In this case, the high-voltage resistor RHV is used essentially as a voltage divider.

The fact is noteworthy that the substrate voltage Vs applied to the high-voltage resistor R_{HV} may be a high value in either of the exemplary applications just discussed with reference to FIGS. 1 and 2.

The voltage fraction utilized as a drive signal to the linear region (second circuit structure C2), and the current flowing through the high-voltage resistor (first circuit structure C1), should have comparable values with, and be no higher than, the maximum voltage of the semiconductor well wherein the signal circuitry is integrated, respectively the maximum current anticipated for specific circuit structures.

This requires that the high-voltage resistor R_{HV} be a suitable resistive value to provide the voltage division, respectively the current, demanded by the drive circuitry in the circuit structure employed.

This resistance may be as high as a few MΩ, and is never less than a few tens kΩ.

Such high resistances involve the use of integrated resistive structures having layers of high resistivity and/or substantial length.

On the one hand, integrating high-voltage resistive structures of conventional design requires fairly large silicon space, i.e., chip surface space, even when resistive layers with the highest resistance allowed by technology are provided.

On the other hand, providing long resistive structures makes the use of layouts effective to minimize silicon occupation for a given area a necessity.

In particular, an exemplary layout of long resistive structures according to the prior art is shown in FIGS. 3 and 4, wherein a winding P-type region 2′ is formed in an N-type substrate 1′.

However, this layout also is difficult to use with high-voltage resistive structures, on account of its heavy silicon space requirements.

This is due to that, in reverse biasing a portion of doped silicon, the width of the depletion region 3′, shown in ghost lines in FIGS. 3 and 4, is inversely proportional to the dopant concentration (and, therefore, directly proportional to the structure resistance). Consequently, the spread of this depletion region would prove considerable in high-voltage resistive structures.

Furthermore, although high-voltage resistive structures may be integrated using the most resistive layers afforded by technology, VIPower devices capable of accommodating high voltages are bound to have a substrate resistivity several orders of magnitude higher than the most resistive layers obtainable with current technological processes. Consequently, layouts conceived to optimize the silicon area available on a chip like that shown in FIG. 3 may develop a pinch-off problem.

In particular, on the occurrence of a pinch-off, the depletion regions 3′ of two or more rungs of the resistive structure would come in contact, as shown in the right-hand portion of FIG. 4, resulting in the resistive value of the structure, and hence the operability of the host circuitry, being affected.

To overcome this, it is necessary that in planning the layout of a high-voltage resistive structure, care be taken to have the spacing between rungs of the winding structure greater than the combined widths of the depletion regions pertaining to each of the rungs. This means that the rungs of the resistive structure being applied to a high voltage should be spaced apart to suit the voltage drop across the resistive structure.

As a result, the layout of FIG. 3 would take the space-intensive form shown in FIG. 5, in the instance of high-voltage resistive structures.

In addition, the high voltage value at the resistive structure makes it necessary to provide edge structures effectively safeguarding the regions most concerned by high voltages against premature breakdowns. In this case, metal field plates or high-resistive structure rings may have to be used, which just magnifies the demand for silicon area.

Finally, the layer wherein the resistive structure is to be integrated may be enhanced to diminish the lateral depletion region between rungs of the resistive structure.

This approach reduces, however, the voltage capacity of the whole device because, to produce a narrower depletion region, a very high dopant concentration is required in the surface region, resulting in a lower critical electric field.

Similar considerations as those above also apply to a high-voltage resistive structure integrated around the high-voltage region encircling a power device. In this way, and especially with a device of large area, a resistive structure whose length is a fraction of the device perimeter, or at most same as or twice that perimeter, can provide the resistive structure sought.

In this case, the distance to be taken into account at the designing stage is that between the rungs of the resistive structure and the well wherein the power device is formed.

The underlying technical problem of this invention is to provide a resistive structure, integrated in a semiconductor substrate, with such structural and functional features that it can accept high voltages and yet require no inordinate amount of silicon area, thereby overcoming the limitations of prior resistive structures.

### SUMMARY OF THE INVENTION

The principle on which this invention stands is one of providing a resistive structure which is isolated dielectrically, integrated in a semiconductor substrate, suitable for low- and high-voltage applications, and occupies far less silicon area than prior designs, using a dielectric trench structure which is filled with polysilicon.

Based on this principle, the technical problem is solved by a resistive structure as previously indicated and defined in the characterizing portion of claim 1.

The features and advantages of a resistive structure according to the invention will become apparent from the following description of embodiments thereof, given by way of non-limitative examples with reference to the accompanying drawings.

### BRIEF DESCRIPTION OF THE DRAWINGS

In the drawings:

FIG. 1 illustrates schematically a first exemplary application of a conventional high-voltage resistor;

FIG. 2 illustrates schematically a second exemplary application of a conventional high-voltage resistor;

FIG. 3 shows an exemplary layout of a conventional long high-voltage resistive structure;

FIG. 4 shows a vertical cross-section taken through the layout of FIG. 3 along line IV-IV;

FIG. 5 shows another exemplary layout of a conventional long high-voltage resistive structure;

FIG. 6 shows an integrated resistive structure according to the invention;

FIG. 7 shows a modified embodiment of the integrated resistive structure according to the invention;

FIG. 8 shows a second modified embodiment of the integrated resistive structure according to the invention;

FIG. 9 shows a third modified embodiment of the integrated resistive structure according to the invention;

FIG. 10 shows a fourth modified embodiment of the integrated resistive structure according to the invention;

FIG. 11 is a detail view of a fifth modified embodiment of the integrated resistive structure according to the invention; and

FIG. 12 shows a sixth modified embodiment of the integrated resistive structure according to the invention.

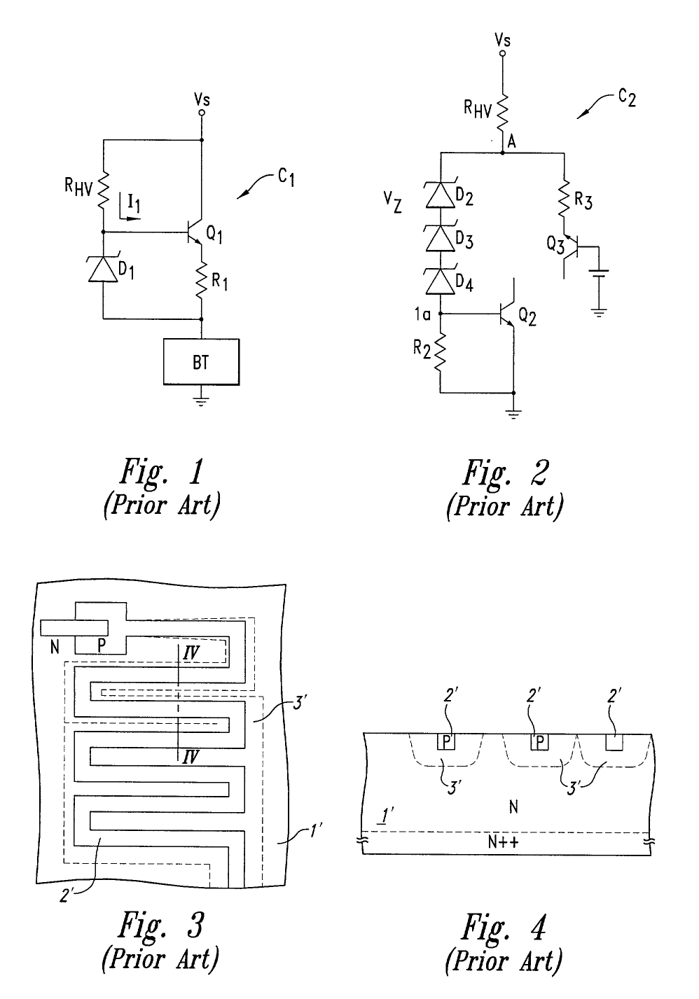

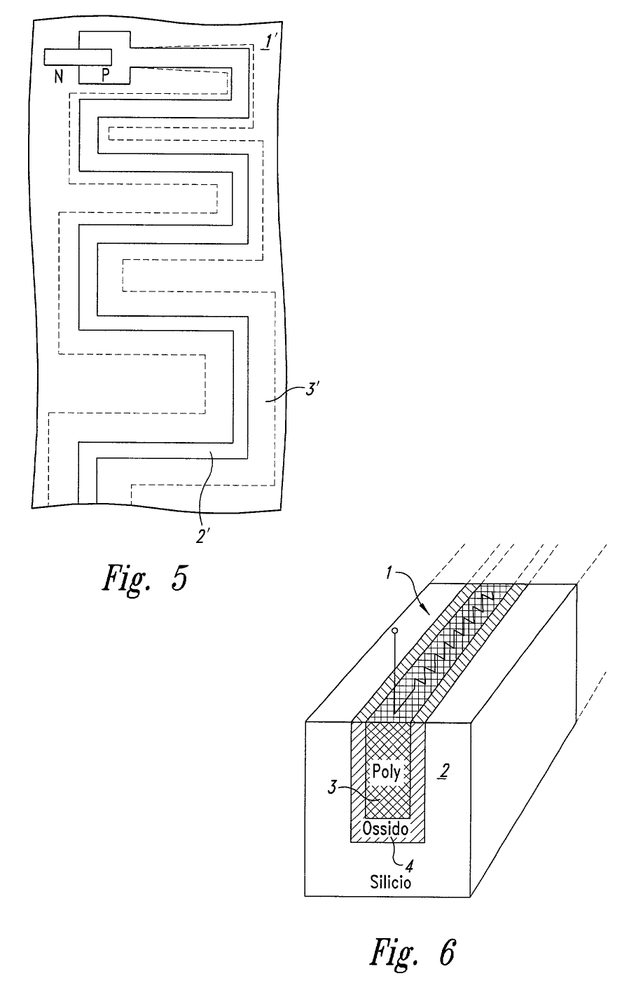

### DETAILED DESCRIPTION OF THE INVENTION

With reference to FIG. 6, a resistive structure according to the invention is shown generally at 1.

In particular, this resistive structure 1 is formed in a semiconductor substrate 2, using a doped polysilicon region 3 which is surrounded completely by a dielectric region 4, specifically a dielectric trench structure. Advantageously in this invention, the resistive structure 1 is, therefore, fully isolated dielectrically, not just vertically as in prior designs.

In this way, the dielectric region 4 will encircle the perimeter of the resistive structure 1, and the depletion region will be confined therein. Advantageously in this invention, a single dielectric trench is provided and the resistive structure forms a part of this, being as it is formed from the trench fill material.

In other words, in a biased condition of the semiconductor substrate 2, the presence of the dielectric region 4 close to the outer region of the resistive structure 1 allows the field lines to surface through the dielectric region 4.

It should be noted that, with the dielectric trench structure 4 much smaller in width than the size of the aforementioned depletion region needed in conventional resistive structures, the electric field applied to it will be higher for the same applied voltage. The dielectric layer that isolates the resistive structure, being obtained in the process of oxidizing the trench sidewalls, can be made quite thin, in fact, and still ensure electrical isolation.

In fact, the dielectric trench structure 4 used in the resistive structure 1 of this invention can accommodate high voltage values, by reason of the value of the critical electric field in the dielectric oxide which comprises the structure being much higher than the critical value in the silicon. Specifically, the value of the critical electric field in the oxide is on the order of 600V/μm, compared to standard values of 20V/μm for the silicon used in conventional high-voltage structures.

In addition, the dielectric region about the resistive structure ensures isolation of the latter from other external components integrated in the same semiconductor substrate 2, with respect to both leakage and parasitic capacitances.

Advantageously, the vertical dimensions (width and depth) of the dielectric trench structure 4 are selected larger than those of the doped polysilicon region 3, so as to safeguard the resistive structure from premature breakdowns.

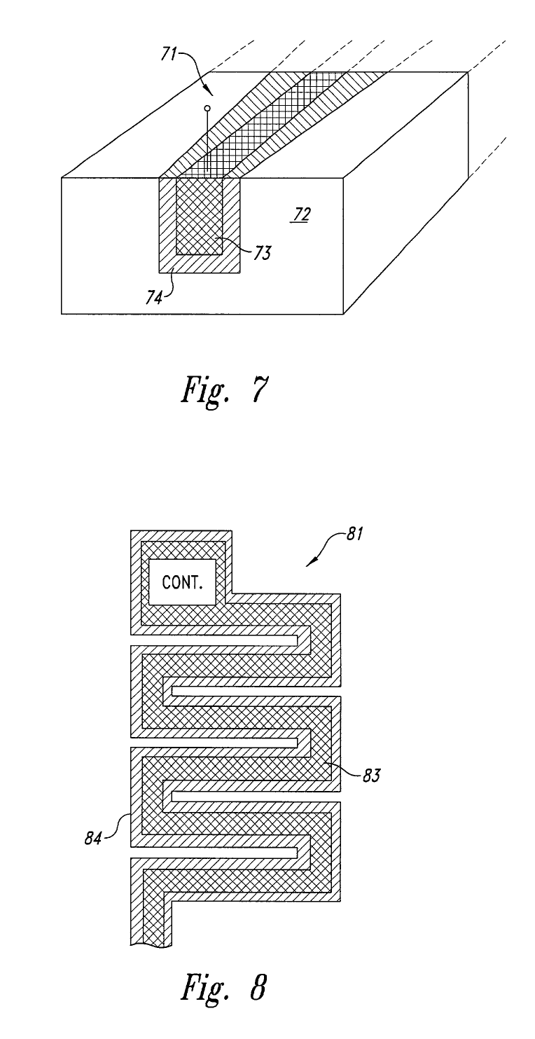

A specially advantageous embodiment of the invention is generally shown at 71 in FIG. 7. The resistive structure 71 is formed in a semiconductor substrate 72 using a doped polysilicon region 73. Several trenches of a suitable area are provided in the most concerned portions of the resistive structure 71 with high voltage, and are distributed about the doped region 73 to produce a single dielectric region 74.

The aperture of the trenches intended to form the dielectric region 74 following oxidation is smaller than the aperture of the trench which is to contain the polysilicon forming the resistive structure 71. In particular, the trench wherein the resistive structure is to be formed should emerge from the oxidizing step with an aperture effective to prevent its sidewalls from contacting each other, so that it can later be filled with polysilicon.

It should be noted that this dielectric region 74 may be given different widths, using a plurality of suitably spaced trenches, according to the voltage drop seen by the various rungs of the winding resistive structure 71.

In order to greatly increase the resistive value of the dielectrically isolated resistive structure of this invention, winding resistive structures 81 are provided, as shown in FIG. 8, so that a resistive element of great length can be obtained for a limited integration area.

In the winding resistive structure 81, the dielectric region 84 also surrounds the polysilicon region 84 completely, both regions conforming to the winding shape of the resistive structure 81.

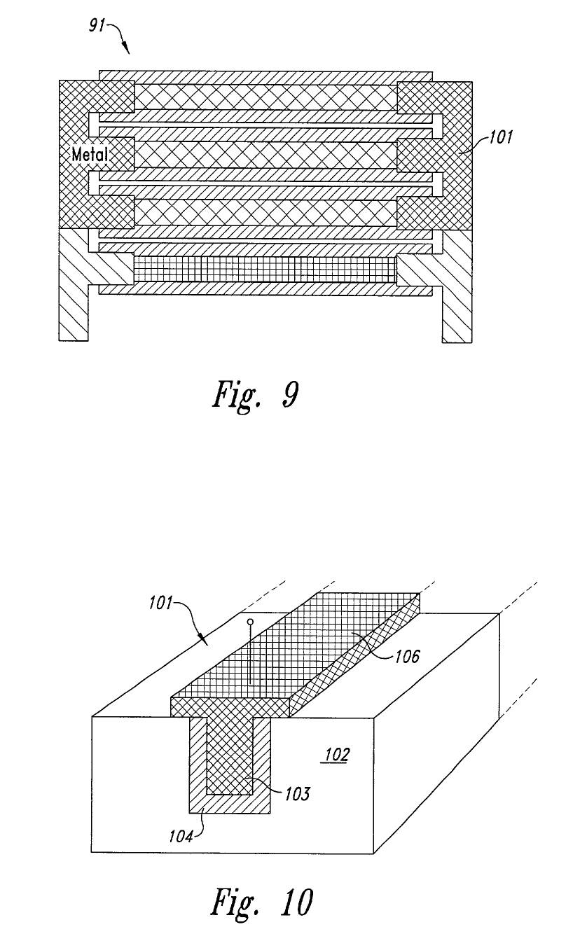

A third embodiment of a dielectrically isolated resistive structure according to the invention is shown generally and schematically at 91 in FIG. 9.

In particular, the rungs of the resistive structure 91 are connected together in parallel by a metallization 95. The equivalent resistance of the resulting structure is, therefore, n times smaller than the resistance of each rung of the structure, n being the number of rungs linked together by the metallization 95.

In this way, resistive structures of controlled resistance can be obtained by the resistance of each rung of the resistive structure according to the invention can be set in a positive manner, these being resistive elements formed from polysilicon and isolated dielectrically.

Shown in FIG. 10 is a fourth embodiment of the resistive structure according to the invention, generally designated 101.

In particular, the resistive structure 101 is formed in a semiconductor substrate 102 using a polysilicon fill layer 103 of an oxide trench 104, the layer 103 being masked off and then etched away to yield a T-shaped structure 106, as shown in FIG. 10, rather than being planarized by a chemical etching step across its surface.

In other words, the T-shaped structure 106 retains polysilicon connection paths. Low-resistance resistive structures are thus provided which can be connected to other components through this T-shaped structure 106, being integral with the resistive structure and functioning as field plates in the instance of high-voltage applications.

Advantageously in this invention, all of the above-discussed embodiments of the dielectrically isolated resistive structure utilize a fill polysilicon of the dielectric trenches which is suitably doped either by implantation or during a depositing step (so-called in situ doping).

Where doping is effected by implantation, only the surface region of the fill polysilicon would be enhanced. In this case, the equivalent resistance of the resulting structure would be a parallel of surface resistance (enhanced region with dopant) and bulk resistance (undoped region).

It should be noted that in the parallel arrangement, bulk resistance might prove almost trivial as against the implanted amount, on account of the high resistivity of doped polysilicon and the small cross-section of the oxidized sidewalls.

In particular, by not doping the bulk region, the structure capacitance to the substrate (polysilicon/oxide/silicon) can be lowered, to the benefit of high-frequency applications.

Also, as the implanted dosage is varied, the resistance value of the resistive structure formed by implantation is also varied. Thus, implantations provided by standard processes for fabricating the remainder of the circuitry integrated along with the resistive structure (P and N implantations) to obtain different types of resistive structures, each with a different resistance value, may be used.

If the fill polysilicon of the dielectric trench cannot be doped in situ, then a step of doubly depositing undoped polysilicon and a step of enhancing by implantation are carried out directly after the first deposition of polysilicon.

Angled implants show to be advantageous in this case.

In the construction of dielectrically isolated resistive structures according to the invention, as shown schematically in FIG. 11, the thickness of the first-deposited polysilicon should conform to the sidewalls of the dielectric trench 114. This will prevent the trench from being filled completely, so that the subsequent implanting and doping steps can be correctly carried out to the specified depth.

Advantageously in this invention, the compact size of the resistive structure thus obtained enables the resistive structure to be integrated adjacent to an edge structure 117, as shown in FIG. 11. Thus, for example, an edge structure integrated annularly about the device incorporating the resistive structure of this invention can be used to further reduce the area requirements of the finished device.

In addition, by implementing the dielectric trench structure in the form of a plurality of small trenches, the dielectric region that encircles the resistive structure-forming polysilicon can be made very thin indeed, compared to prior art embodiments. Thus, for a given silicon occupation, very long resistive elements having, therefore, higher resistance values can be integrated, or in a dual fashion, the silicon occupation can be diminished for a given resistance value.

It should be noted that a resistive structure according to the invention can also be used with low-voltage devices.

Compared to resistive elements according to the prior art, the dielectric region which surrounds the polysilicon forming the resistive element according to the invention provides for electrical isolation of the resistive structure thus obtained from other circuit components integrated along with it, affords increased integration density, and above all, reduces parasitic capacitances.

In particular, in low-voltage applications, the thickness of the dielectric used for isolating the resistive structure can be further reduced without affecting its isolation and resistance to leakage currents.

Reducing the parasitic capacitances is of special interest to high-frequency applications. In this case, it suffices that the dielectric region about the polysilicon that forms the resistive element is suitably dimensioned to minimize the capacitance associated therewith.

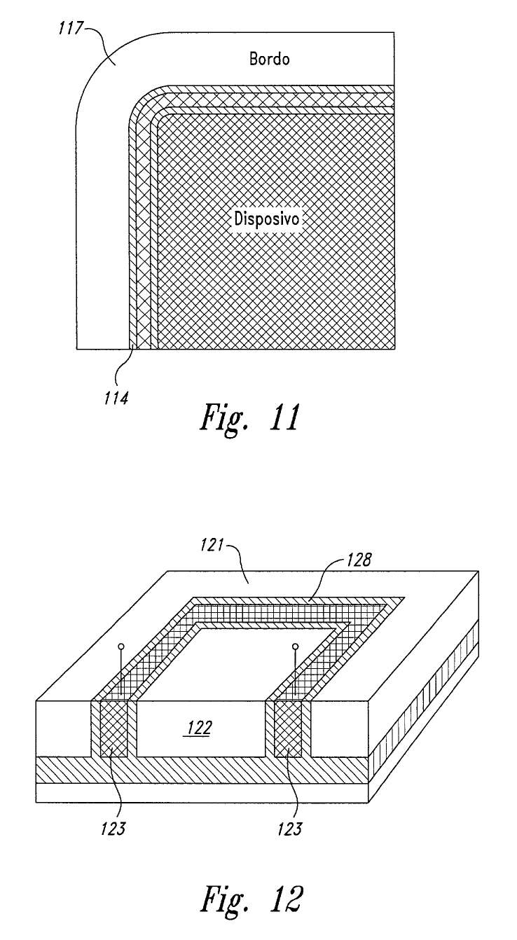

Finally, the resistive structure of this invention may be used to advantage in any devices that are integrated in substrates of the SOI type, as shown schematically in FIG. 12.

As is known, wells are isolated in such devices by means of a dielectric trench 128. Accordingly, a resistive structure 121 according to the invention can be integrated in a semiconductor substrate 122 by introducing doped polysilicon 123 into the existing trenches 128, in between wells, and would require no additional integration area.

The capacitive contribution from a thus integrated resistive structure 121, to the bulk associated with a polysilicon/oxide/substrate capacitance, is minimal because of the buried oxide thickness never being less than 0.4 microns. Also, as said before, this capacitive contribution can be further reduced if deep doping is omitted and only the surface portion is doped by implantation, consistently with intended applications of the resistive structure.

1. A resistive structure, integrated in a semiconductor substrate, comprising a suitably doped polysilicon region completely surrounded by a dielectric region, so that the resistive structure is isolated electrically from other components jointly integrated in the semiconductor substrate.

2. The resistive structure of claim 1, wherein portions of the resistive structure are formed with a plurality of trenches having suitable areas and are distributed about the polysilicon region to form a single dielectric region.

3. The resistive structure of claim 1, wherein said polysilicon region and said dielectric region are winding patterns, thereby reducing the space requirements of the resistive structure for a given resistance value.

4. The resistive structure of claim 3, wherein said winding patterns are formed to include rungs, said rungs are connected in parallel together by a metallization.

5. The resistive structure of claim 1, wherein said polysilicon region is masked and then etched to create a T-shaped structure providing connection paths of polysilicon.

6. The resistive structure of claim 1, wherein said polysilicon region comprises fill polysilicon that has been enhanced by implantation in its surface region only.

7. The resistive structure of claim 1, wherein said polysilicon region comprises two deposited layers of undoped polysilicon, only a firs t of said layers being enhanced by implantation to lower the values of parasitic capacitances associated with the resistive structure.

8. The resistive structure of claim 7, wherein said first polysilicon layer is enhanced by angled implantation and has a thickness dimension conforming to the sidewalls of the dielectric region to prevent said region from becoming filled completely.

9. The resistive structure of claim 1, wherein said semiconductor substrate is a SOI substrate and comprises a plurality of dielectric trenches between wells of integrated devices therein, and that doped polysilicon intended to form the resistive structure is introduced into said trenches, the resistive structure itself requiring no additional integration area.

10. The resistive structure of claim 1, wherein said dielectric region that is arranged to isolate the resistive structure is formed in the process of oxidizing the sidewalls of a dielectric trench.

11. An integrated resistive structure, comprising:
at least one trench having sidewalls formed in a semiconductor substrate;
a dielectric layer entirely coating all walls of the at least one trench; and
a polysilicon region filling the at least one trench to be isolated dielectrically from the semiconductor substrate.

12. The structure of claim 11, wherein the dielectric layer comprises a dielectric oxide formed from oxidizing the walls of the at least one trench.

13. The structure of claim 12, wherein the dielectric layer has vertical and horizontal dimensions that are greater than vertical and horizontal dimensions of the polysilicon region.

14. The structure of claim 11, wherein the polysilicon region has a T-shaped cross-sectional configuration with a stem portion filling the at least one trench and a cap portion covering the at least one trench and overlapping a portion of a top surface of the silicon substrate on each side of the at least one trench.

15. The structure of claim 11, wherein the polysilicon region includes a doped surface region.

16. The structure of claim 11, wherein the polysilicon region comprises first and second layers of polysilicon, the second layer being undoped and the first layer implanted with a dopant.

17. The structure of claim 16, wherein the first layer of polysilicon is implanted by angled implantation and has a thickness dimension conforming to the walls of the dielectric-coated at least one trench to prevent complete filling of the at least one trench.

18. The substrate of claim 11, comprising a plurality of trenches coupled together electrically by metallization.
